(19) United States
(12) Patent Application Publication
(10) Pub. No.: US 2026/0215190 A1
(43) Pub. Date: Jul. 23, 2026

(54) ETCHING METHOD AND PLASMA PROCESSING APPARATUS

(71) Applicant: Tokyo Electron Limited, Tokyo (JP)

(72) Inventors: Akihiro ISHII, Miyagi (JP); Taku GOHIRA, Miyagi (JP)

(73) Assignee: Tokyo Electron Limited, Tokyo (JP)

(21) Appl. No.: 19/568,282

(22) Filed: Mar. 16, 2026

Related U.S. Application Data
(63) Continuation of application No. PCT/JP2024/030506, filed on Aug. 27, 2024.

(30) Foreign Application Priority Data
Sep. 28, 2023 (JP) 2023-167773

(51) Int. Cl. H10P 50/00; H01J 37/32; H10P 14/69; H10P 50/28

(52) U.S. Cl. CPC H10P 50/73; H01J 37/32449; H10P 14/6903; H10P 50/283; H01J 2237/334

(57) ABSTRACT

An etching method includes: (a) a step of loading a substrate into a chamber of a plasma processing apparatus, wherein the substrate has a silicon-containing film and a mask provided on the silicon-containing film, and the silicon-containing film includes at least one element selected from the group consisting of nitrogen, phosphorus, and boron; and (b) a step of exposing the substrate to plasma generated from a processing gas including a hydrogen fluoride gas, wherein (b) includes a step of forming a recess in the silicon-containing film and a step of forming a protective film including the at least one element on a sidewall of the recess.

### CROSS-REFERENCE TO RELATED APPLICATIONS

This application is a continuation application of PCT Application No. PCT/JP2024/030506, filed on Aug. 27, 2024, which claims the benefit of priority from Japanese Patent Application No. 2023-167773, filed on Sep. 28, 2023. The entire contents of the above listed PCT and priority applications are incorporated herein by reference.

### BACKGROUND

### Field

Exemplary embodiments of the present disclosure relate to an etching method and a plasma processing apparatus.

### Description of the Related Art

In manufacturing of electronic devices, plasma etching of a silicon-containing film of a substrate is performed. In plasma etching, etching of the silicon-containing film is performed using plasma generated from a processing gas. U.S. Patent Application Publication No. 2016/0343580 discloses a processing gas including a fluorocarbon gas as a processing gas used for plasma etching of a silicon-containing film. Japanese Unexamined Patent Application Publication No. 2016-39310 discloses a processing gas including a hydrocarbon gas and a hydrofluorocarbon gas as a processing gas used for plasma etching of a silicon-containing film.

### SUMMARY

Disclosed herein is an etching process. An etching method includes: (a) loading a substrate into a chamber of a plasma processing apparatus, wherein the substrate has a silicon-containing film and a mask provided on the silicon-containing film, and the silicon-containing film includes at least one element selected from the group consisting of nitrogen, phosphorus, and boron; and (b) exposing the substrate to plasma generated from a processing gas including a hydrogen fluoride gas, wherein the step (b) includes forming a recess in the silicon-containing film and a step of forming a protective film including the at least one element on a sidewall of the recess.

### BRIEF DESCRIPTION OF THE DRAWINGS

FIG. 1 is a diagram schematically illustrating a plasma processing apparatus according to one exemplary embodiment.

FIG. 2 is a diagram schematically illustrating a plasma processing apparatus according to one exemplary embodiment.

FIG. 3 is a flowchart of an etching method according to one exemplary embodiment.

FIG. 4 is a cross-sectional view of an example of a substrate to which the method of FIG. 3 can be applied.

FIG. 5 is a cross-sectional view of another example of a substrate to which the method of FIG. 3 can be applied.

FIG. 6 is a cross-sectional view of still another example of a substrate to which the method of FIG. 3 can be applied.

FIG. 7 is a cross-sectional view illustrating one step of an etching method according to one exemplary embodiment.

FIG. 8 is a diagram illustrating an example of experimental results regarding a difference in etching rate according to a ratio of nitrogen contained in a silicon-containing film.

### DETAILED DESCRIPTION

In the following description, with reference to the drawings, the same reference numbers are assigned to the same components or to similar components having the same function, and overlapping description is omitted.

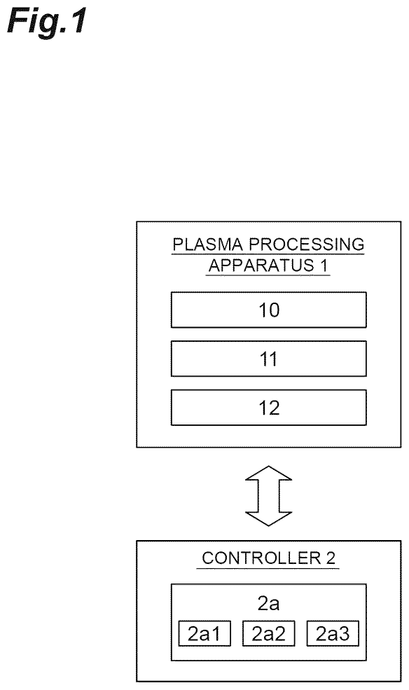

FIG. 1 is a diagram schematically illustrating a plasma processing apparatus according to one exemplary embodiment. In one embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas to the plasma processing space, and at least one gas exhaust port for exhausting gas from the plasma processing space. The gas supply port is connected to a gas supply 20 described later, and the gas exhaust port is connected to an exhaust system 40 described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), or a surface wave plasma (SWP), or the like. Further, various types of plasma generators may be used, including an AC (Alternating Current) plasma generator and a DC (Direct Current) plasma generator. In one embodiment, an AC signal (AC power) used in the AC plasma generator has a frequency in a range of 100 kHz to 10 GHz. Therefore, the AC signal includes an RF (Radio Frequency) signal and a microwave signal. In one embodiment, the RF signal has a frequency in a range of 100 kHz to 150 MHz.

The controller 2 processes computer-executable instructions that cause the plasma processing apparatus 1 to execute various steps described in the present disclosure. The controller 2 may be configured to control each element of the plasma processing apparatus 1 to execute the various steps described herein. In one embodiment, a part or all of the controller 2 may be included in the plasma processing apparatus 1. The controller 2 may include a processor 2a1, a storage unit 2a2, and a communication interface 2a3. The controller 2 is realized by, for example, a computer 2a. The processor 2a1 may be configured to read a program from the storage unit 2a2 and execute the read program to perform various control operations. This program may be stored in the storage unit 2a2 in advance, or may be acquired via a medium when necessary. The acquired program is stored in the storage unit 2a2, and is read from the storage unit 2a2 and executed by the processor 2a1. The medium may be various storage media readable by the computer 2a, or may be a communication line connected to the communication interface 2a3. The processor 2a1 may be a CPU (Central Processing Unit). The storage unit 2a2 may include a RAM (Random Access Memory), a ROM (Read Only Memory), an HDD (Hard Disk Drive), an SSD (Solid State Drive), or a combination thereof. The communication interface 2a3 may communicate with the plasma processing apparatus 1 via a communication line such as a LAN (Local Area Network).

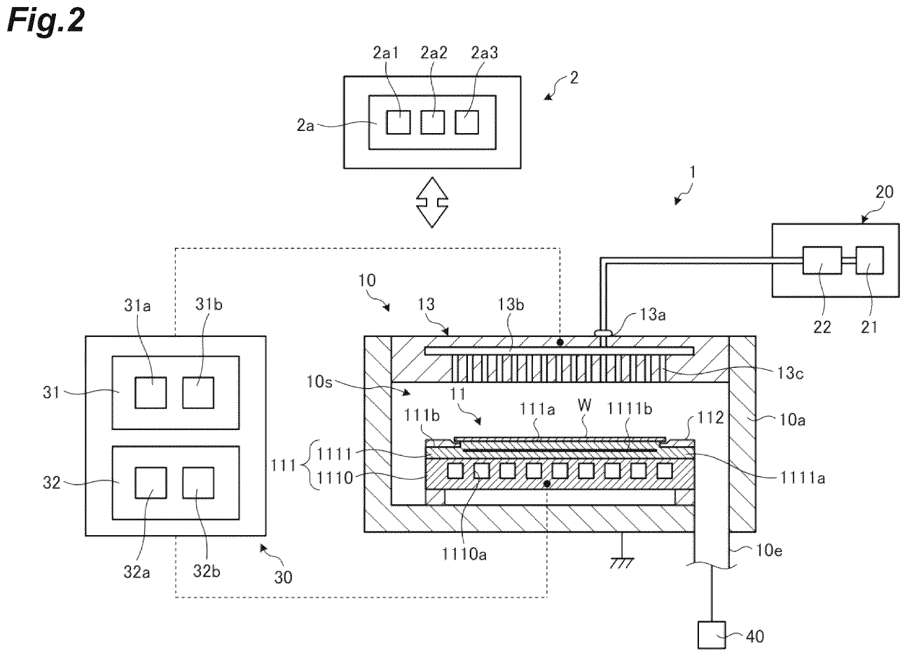

Hereinafter, a configuration example of a capacitively coupled plasma processing apparatus as an example of the plasma processing apparatus 1 will be described. FIG. 2 is a diagram schematically illustrating a plasma processing apparatus according to one exemplary embodiment.

The capacitively coupled plasma processing apparatus 1 includes a plasma processing chamber 10, a gas supply 20, a power supply 30, and an exhaust system 40. Further, the plasma processing apparatus 1 includes a substrate support 11 and a gas introduction part. The gas introduction part is configured to introduce at least one processing gas into the plasma processing chamber 10. The gas introduction part includes a showerhead 13. The substrate support 11 is disposed in the plasma processing chamber 10. The showerhead 13 is disposed above the substrate support 11. In one embodiment, the showerhead 13 constitutes at least a part of a ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Note that other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32 described later may be disposed in the ceramic member 1111a. In this case, the at least one RF/DC electrode functions as a lower electrode. When a bias RF signal and/or a DC signal described later is supplied to the at least one RF/DC electrode, the RF/DC electrode is also called a bias electrode. Note that the conductive member of the base 1110 and the at least one RF/DC electrode may function as a plurality of lower electrodes. Further, the electrostatic electrode 1111b may function as a lower electrode. Therefore, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid such as brine or gas flows through the flow path 1110a. In one embodiment, the flow path 1110a is formed in the base 1110, and one or more heaters are disposed in the ceramic member 1111a of the electrostatic chuck 1111. Further, the substrate support 11 may include a heat transfer gas supply unit configured to supply a heat transfer gas to a gap between a back surface of the substrate W and the central region 111a.

The showerhead 13 is configured to introduce at least one processing gas from the gas supply 20 into the plasma processing space 10s. The showerhead 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the showerhead 13 includes at least one upper electrode. Note that the gas introduction part may include, in addition to the showerhead 13, one or more side gas injectors (SGI) attached to one or more openings formed in the sidewall 10a.

The gas supply 20 may include at least one gas source 21 and at least one flow rate controller 22. In one embodiment, the gas supply 20 is configured to supply at least one processing gas from a respective corresponding gas source 21 through a respective corresponding flow rate controller 22 to the showerhead 13. Each flow rate controller 22 may include, for example, a mass flow controller or a pressure-controlled flow rate controller. Furthermore, the gas supply 20 may include at least one flow modulation device that modulates or pulses a flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. Thereby, plasma is formed from the at least one processing gas supplied to the plasma processing space 10s. Therefore, the RF power supply 31 can function as at least a part of the plasma generator 12. Further, by supplying a bias RF signal to the at least one lower electrode, a bias potential is generated on the substrate W, and ion components in the formed plasma can be drawn to the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to at least one lower electrode via at least one impedance matching circuit and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power supply 30 may include a DC power supply 32 coupled to the plasma processing chamber 10. The DC power supply 32 includes a first DC generator 32a and a second DC generator 32b. In one embodiment, the first DC generator 32a is connected to at least one lower electrode and is configured to generate a first DC signal. The generated first DC signal is applied to the at least one lower electrode. In one embodiment, the second DC generator 32b is connected to at least one upper electrode and is configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulse may have a pulse waveform of a rectangle, a trapezoid, a triangle, or a combination thereof. In one embodiment, a waveform generator for generating a sequence of voltage pulses from a DC signal is connected between the first DC generator 32a and at least one lower electrode. Therefore, the first DC generator 32a and the waveform generator constitute a voltage pulse generator. When the second DC generator 32b and a waveform generator constitute a voltage pulse generator, the voltage pulse generator is connected to at least one upper electrode. The voltage pulse may have a positive polarity or may have a negative polarity. Further, the sequence of voltage pulses may include one or more positive polarity voltage pulses and one or more negative polarity voltage pulses within one cycle. Note that the first and second DC generators 32a and 32b may be provided in addition to the RF power supply 31, or the first DC generator 32a may be provided instead of the second RF generator 31b.

The exhaust system 40 can be connected to, for example, a gas exhaust port 10e provided at a bottom of the plasma processing chamber 10. The exhaust system 40 may include a pressure regulating valve and a vacuum pump. The pressure in the plasma processing space 10s is adjusted by the pressure regulating valve. The vacuum pump may include a turbomolecular pump, a dry pump, or a combination thereof.

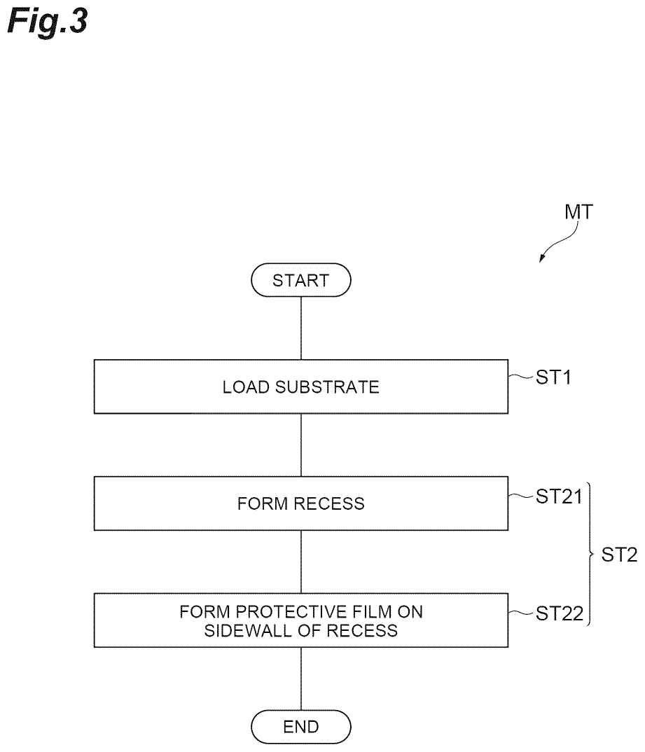

FIG. 3 is a flowchart of an etching method according to one exemplary embodiment. An etching method MT (hereinafter, referred to as “method MT”) shown in FIG. 3 can be executed by the plasma processing apparatus 1 of the above-described embodiment. The method MT can be applied to a substrate W.

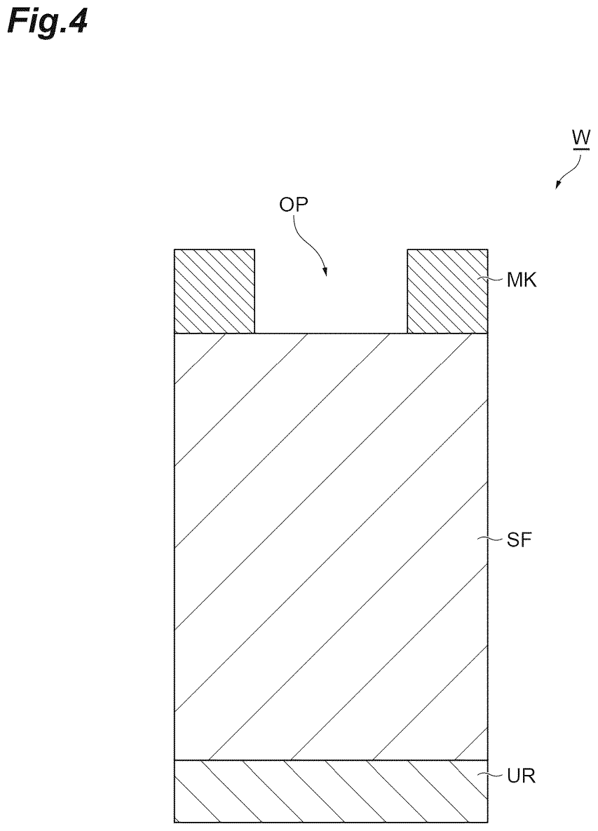

FIG. 4 is a cross-sectional view of an example of a substrate W to which the method MT can be applied. The substrate W shown in FIG. 4 is used, for example, for manufacturing devices such as a DRAM and a 3D-NAND. The substrate W has a silicon-containing film SF. The substrate W may further have an underlying region UR. The silicon-containing film SF may be provided on the underlying region UR. The underlying region UR may include a material different from a material included in the silicon-containing film SF. The underlying region UR may include silicon.

The silicon-containing film SF includes at least one element (hereinafter, also referred to as an additive element) selected from the group consisting of nitrogen (N), phosphorus (P), and boron (B). The silicon-containing film SF may include nitrogen, and may include at least one element selected from the group consisting of phosphorus and boron. The silicon-containing film SF may include at least one selected from the group consisting of a silicon nitride film and a silicon oxynitride film. The silicon-containing film SF may include a silicon oxide film including the additive element. The silicon-containing film SF may include a multilayer film including alternately stacked silicon oxide films and silicon nitride films. In this case, the silicon oxide film may include the additive element, or the silicon nitride film may include at least one element selected from the group consisting of phosphorus and boron.

The additive element may be doped when the silicon-containing film SF is formed. For example, when the silicon-containing film SF is formed by CVD, a gas including the additive element may be included in a source gas. Alternatively, the additive element may be doped after the silicon-containing film SF is formed. For example, the additive element may be doped into the silicon-containing film SF by an ion implantation method.

A ratio of the additive element contained in the silicon-containing film SF may be 10 atomic % or less. The ratio of the additive element may be 8 atomic % or less. The ratio of the additive element may be 6 atomic % or less. The ratio of the additive element may be 1 atomic % or more. The ratio of the additive element may be 2 atomic % or more. The ratio of the additive element may be 0.5 atomic % or more. When a plurality of elements among nitrogen, phosphorus, and boron are included in the silicon-containing film SF, the ratio of the additive element may be a total value of atomic % of each element.

The atomic % may be a value obtained by dividing a ratio of a mass of the additive element to a total mass of the silicon-containing film SF by an atomic weight of the additive element. For example, when a silicon nitride film contains 95% by mass of silicon and 5% by mass of nitrogen, a value obtained by dividing 95% by mass by 28, which is the atomic weight of silicon, is 3.39. A value obtained by dividing 5% by mass by 14.1, which is the atomic weight of nitrogen, is 0.35. When these values are expressed as a percentage, the atomic % of silicon is 90.6 atomic % and the atomic % of nitrogen is 9.4 atomic %. A method for measuring the atomic % is, for example, Secondary Ion Mass Spectrometry (SIMS) or X-ray Photoelectron Spectroscopy (XPS).

The substrate W further has a mask MK. The mask MK may have an opening OP. The opening OP may have a hole pattern or a line pattern. The mask MK may be provided on the silicon-containing film SF. The mask MK may include at least one selected from the group consisting of silicon, carbon, and metal. The mask MK may include at least one selected from the group consisting of a silicon-containing film different from the silicon-containing film SF, a carbon-containing film, and a metal-containing film. The silicon-containing film different from the silicon-containing film SF may include a polysilicon film. The carbon-containing film may include an amorphous carbon film. The metal-containing film may include at least one metal selected from the group consisting of tungsten (W), titanium (Ti), and ruthenium (Ru).

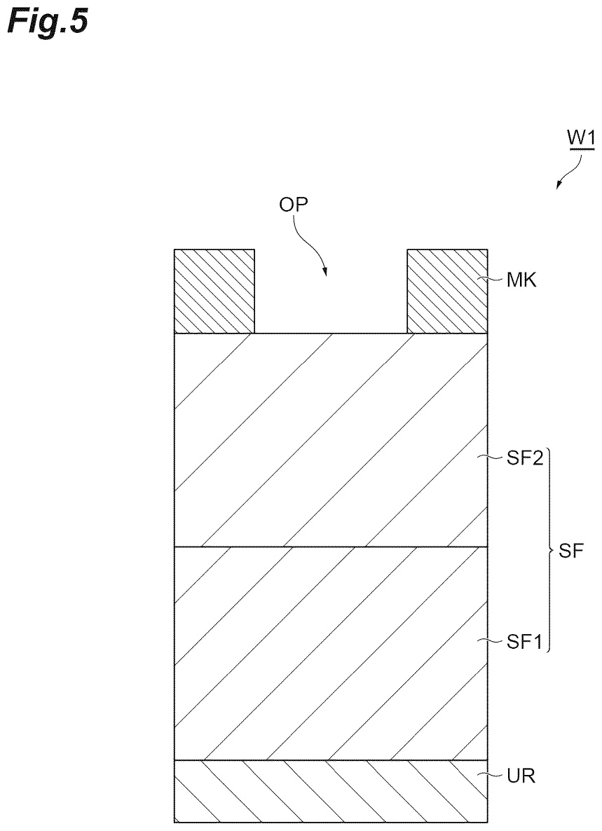

FIG. 5 is a cross-sectional view of another example of a substrate W1 to which the method MT can be applied. The silicon-containing film SF may include a first region SF1 and a second region SF2. The first region SF1 may include the additive element at a first ratio, and the second region SF2 may include the additive element at a second ratio different from the first ratio. The second ratio may be smaller than the first ratio, or may be larger than the first ratio. The first ratio and the second ratio may be the above-described atomic %. In the example of FIG. 5, the second region SF2 is provided on the first region SF1 in a thickness direction of the substrate W1.

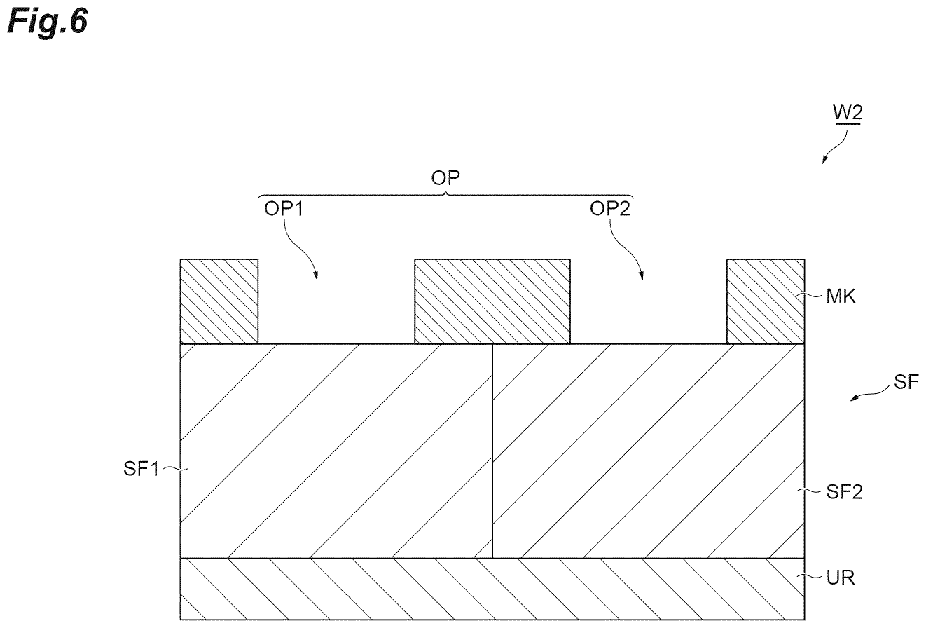

FIG. 6 is a cross-sectional view of still another example of a substrate W2 to which the method MT can be applied. In the substrate W2, the second region SF2 may be arranged alongside the first region SF1 in an in-plane direction of the substrate W2. The in-plane direction of the substrate W2 is a direction orthogonal to a thickness direction of the substrate W2. The opening OP of the mask MK may include a first opening OP1 and a second opening OP2. The mask MK may have the first opening OP1 on the first region SF1 and have the second opening OP2 on the second region SF2. A shape of the first opening OP1 and a shape of the second opening OP2 are different from each other. The first opening OP1 may be a hole-shaped opening. The second opening OP2 may be a slit-shaped opening. In this case, the second ratio in the second region SF2 in which the slit-shaped opening is formed may be different from the first ratio in the first region SF1 in which the hole-shaped opening is formed.

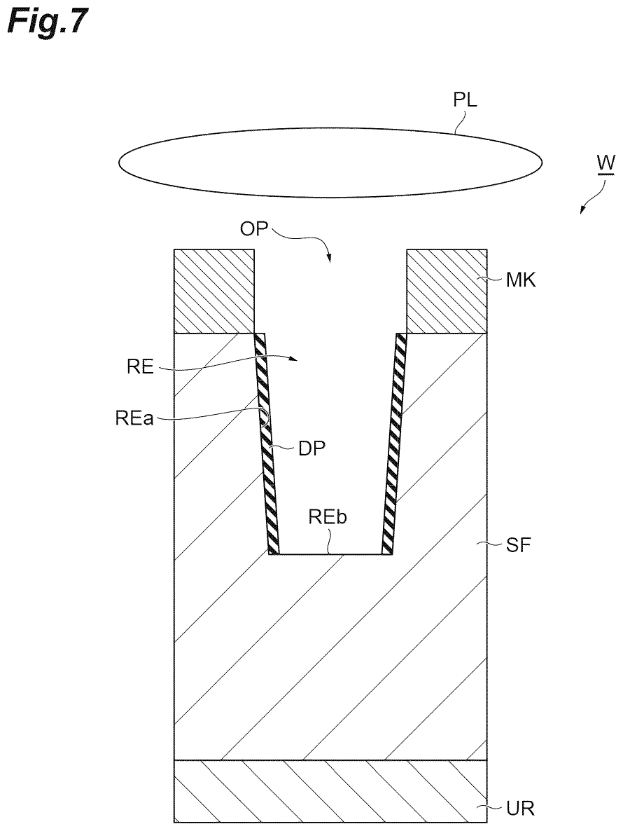

Hereinafter, the method MT will be described with reference to FIGS. 4 and 7, taking as an example a case where the method MT is applied to the substrate W using the plasma processing apparatus 1 of the above-described embodiment. In the following description, the method MT is described as being applied to the substrate W, but the method MT may be applied to the substrate W1 or the substrate W2 instead of the substrate W. Each of FIGS. 4 and 7 is a cross-sectional view illustrating one step of an etching method according to one exemplary embodiment. When the plasma processing apparatus 1 is used, the method MT can be executed in the plasma processing apparatus 1 by control of each part of the plasma processing apparatus 1 by the controller 2. In the method MT, as shown in FIG. 2, the substrate W on the substrate support 11 disposed in the plasma processing chamber 10 is processed.

As shown in FIG. 3, the method MT may include a step ST1 and a step ST2. The step ST1 and the step ST2 can be executed in order.

(Step ST1) In the step ST1, the substrate W shown in FIG. 4 is loaded into the plasma processing chamber 10 by, for example, a transfer device. The substrate W can be supported by the substrate support 11 in the plasma processing chamber 10. In the step ST1, the substrate W having the silicon-containing film SF doped with the additive element is loaded into the plasma processing chamber 10.

(Step ST2) In the step ST2, as shown in FIG. 7, plasma PL is generated from a processing gas, and the substrate W is exposed to the plasma PL. The step ST2 includes a step of forming a recess RE in the silicon-containing film SF by etching (step ST21), and a step of forming a protective film DP including the additive element on a sidewall REa of the recess RE (step ST22). The step ST21 and the step ST22 may be executed simultaneously, or the step ST22 may be executed after the step ST21.

As shown in FIG. 7, a recess RE is formed in the silicon-containing film SF by etching. The recess RE corresponds to the opening OP. The processing gas includes fluorine (F) and hydrogen (H). The processing gas includes, for example, hydrogen fluoride. The plasma PL includes a hydrogen fluoride (HF) etchant, and the recess RE is formed by etching the silicon-containing film SF with the hydrogen fluoride etchant. The hydrogen fluoride etchant may include hydrogen fluoride active species and neutral molecules of hydrogen fluoride. The hydrogen fluoride active species may include hydrogen fluoride ions and hydrogen fluoride radicals. In the plasma PL, since an H-F bond is difficult to dissociate, a hydrogen fluoride etchant having an H-F bond is generated. The hydrogen fluoride etchant may be detected by, for example, a Quadrupole Mass Spectrometer (QMS). Alternatively, the hydrogen fluoride etchant may be detected by, for example, an Optical Emission Spectrometer (OES). In this case, for example, a window (not shown) is provided on the sidewall 10a of the plasma processing chamber 10, and an emission spectrum of the plasma PL acquired from the window may be qualitatively and quantitatively analyzed. The window may be a glass plate, and may be fitted into, for example, a through hole connecting an inside and an outside of the plasma processing chamber 10.

In the step ST2, the processing gas may include a gas of a compound including hydrogen and fluorine, or may be a mixed gas including a hydrogen-containing gas and a fluorine-containing gas. The gas of the compound including hydrogen and fluorine may include at least one selected from the group consisting of a hydrogen fluoride gas and a hydrofluorocarbon gas (CₓH_{y}F_{z} gas). Each of x, y, and z is a positive integer. The hydrogen fluoride gas and the hydrofluorocarbon gas can generate a hydrogen fluoride etchant in the plasma PL. The hydrofluorocarbon gas may be at least one selected from the group consisting of CHF₃, CH₂F₂, CH₃F, C₂HF₅, C₂H₂F₄, C₂H₃F₃, C₂H₄F₂, C₃HF₇, C₃H₂F₂, C₃H₂F₆, C₃H₂F₄, C₃H₃F₅, C₄H₅F₅, C₄H₂F₆, C₅H₂F₁₀, c-C₅H₃F₇, and C₃H₂F₄.

The hydrogen-containing gas included in the mixed gas may include at least one selected from the group consisting of H₂ gas, NH₃ gas, H₂O gas, H₂O₂ gas, and a hydrocarbon gas. The fluorine-containing gas included in the mixed gas may include at least one selected from the group consisting of NF₃ gas, SF₆ gas, WF₆ gas, XeF₂ gas, a fluorocarbon gas, and a hydrofluorocarbon gas. The mixed gas can generate a hydrogen fluoride etchant in the plasma PL.

In the step ST2, the processing gas may include at least one selected from the group consisting of a nitrogen-containing gas, a phosphorus-containing gas, a carbon-containing gas, a gas containing a halogen other than fluorine, a boron-containing gas, and an oxygen-containing gas. The nitrogen-containing gas may include at least one selected from the group consisting of a nitrogen gas (N₂ gas), a nitrogen oxide gas (NO gas), a nitrogen trifluoride gas (NF₃ gas), an ammonia gas (NH₃ gas), a mixed gas of nitrogen gas and hydrogen gas, and an amine gas. The phosphorus-containing gas may include at least one selected from the group consisting of a phosphorus trifluoride gas (PF₃ gas) and a phosphorus pentafluoride gas (PF₅ gas).

The carbon-containing gas may include at least one selected from the group consisting of a fluorocarbon gas (CₓF_{y} gas) and a hydrofluorocarbon gas. The fluorocarbon gas may be at least one selected from the group consisting of CF₄, C₂F₂, C₂F₄, C₃F₈, C₄F₆, C₄F₈, and C₅F₈. The hydrofluorocarbon gas may be at least one selected from CHF₃, CH₂F₂, CH₃F, C₂HF₅, C₂H₂F₄, C₂H₃F₃, C₂H₄F₂, C₃HF₇, C₃H₂F₂, C₃H₂F₆, C₃H₂F₄, C₃H₃F₅, C₄H₅F₅, C₄H₂F₆, C₅H₂F₁₀, c-C₅H₃F₇, and C₃H₂F₄. The halogen-containing gas other than fluorine may include at least one selected from the group consisting of a chlorine-containing gas and a bromine-containing gas. The chlorine-containing gas may include Cl₂ gas. The bromine-containing gas may include HBr gas. The boron-containing gas may include a boron trichloride gas (BCl₃ gas). The oxygen-containing gas may include at least one selected from the group consisting of an oxygen gas (O₂), a carbon monoxide gas (CO), and a carbon dioxide gas (CO₂).

In the step ST2, a temperature of the substrate support 11 that supports the substrate W may be set to 0° C. or lower, may be set to −40° C. or lower, may be set to −60° C. or lower, and may be set to −80° C. or higher. In the step ST2, an electrical bias can be supplied to the substrate support 11.

In the step ST22, the protective film DP may be formed on the bottom surface REb, or the protective film DP may not be formed on the bottom surface REb. A mechanism by which recess formation proceeds on the bottom surface REb is, for example, as follows, but is not limited thereto. In the step ST21, hydrogen fluoride ions are incident on the substrate W along the thickness direction of the substrate W. As a result, the protective film DP formed on the bottom surface REb is removed, and etching proceeds on the exposed bottom surface REb. On the other hand, on the sidewall REa, where hydrogen fluoride ions are less likely to be incident, the protective film DP remains without being removed. Since the protective film DP inhibits entry of hydrogen fluoride radicals into the sidewall REa, recess formation proceeds preferentially on the bottom surface REb, and anisotropic etching is realized.

The protective film DP formed on the sidewall REa in the step ST22 can be generated by a reaction between chemical species in the plasma PL and the silicon-containing film SF including the additive element. When the silicon-containing film SF includes nitrogen, an ammonium salt can be generated by a reaction between the hydrogen fluoride etchant included in the processing gas and the silicon-containing film SF. Therefore, the protective film DP may include an ammonium salt. The ammonium salt may include ammonium fluorosilicate. The ammonium salt may include at least one selected from the group consisting of (NH₄)₂SiF₆, NH₄SiF₅, and (NH₄)₃SiF₇. When the silicon-containing film SF includes phosphorus, a phosphate salt can be generated by a reaction between chemical species in the plasma PL and the silicon-containing film SF. Therefore, the protective film DP may include a phosphate salt. The phosphate salt may include ammonium hexafluorophosphate (NH₄PF₆). When the silicon-containing film SF includes boron, a borate salt can be generated by a reaction between chemical species in the plasma PL and the silicon-containing film SF. Therefore, the protective film DP may include a borate salt. The borate salt may include ammonium tetrafluoroborate (NH₄BF₄).

According to the method MT, adsorption of hydrogen fluoride chemical species on the silicon-containing film SF is promoted by the additive element included in the silicon-containing film SF. A protective film DP is formed on the sidewall REa of the recess RE by a reaction between the silicon-containing film SF including the additive element and the hydrogen fluoride chemical species. The protective film DP suppresses entry of hydrogen fluoride radicals in the hydrogen fluoride chemical species into the sidewall REa of the recess RE, so that etching of the sidewall REa of the recess RE is suppressed. Therefore, it becomes possible to suppress a shape abnormality (bowing) of the sidewall REa of the recess RE. On the other hand, on the bottom surface REb of the recess RE, since formation of the protective film DP is suppressed due to collision of hydrogen fluoride ions in the hydrogen fluoride chemical species, etching is promoted. Since the additive element included in the silicon-containing film SF promotes adsorption of the hydrogen fluoride chemical species on the bottom surface REb of the recess RE, the etching rate of the silicon-containing film SF can be increased.

When the method MT is applied to the substrate W1 shown in FIG. 5, the recess RE can be formed from the second region SF2 to the first region SF1. In the substrate W1, the second region SF2 is provided on the first region SF1 in the thickness direction of the substrate W1. The second ratio may be larger than the first ratio. The higher the ratio of the additive element, the more the adsorption of the hydrogen fluoride etchant is promoted, and the thickness of the protective film DP adhering to the sidewall REa of the recess RE tends to become thicker. By making the second ratio larger than the first ratio, the protective film DP formed on the sidewall REa in the second region SF2 can be made thicker. Therefore, bowing is more easily suppressed on the sidewall REa in the second region SF2. On the other hand, etching proceeds more easily on the sidewall REa in the first region SF1 than on the sidewall REa in the second region SF2. This can suppress the shape of the recess RE from becoming narrower as the distance from the mask MK increases.

The second ratio may be smaller than the first ratio. In this case, adsorption of the hydrogen fluoride chemical species to the bottom surface REb of the recess RE formed in the first region SF1 is promoted. Therefore, the etching rate of the first region SF1 can be increased. Therefore, it is possible to suppress a decrease in the etching rate of the silicon-containing film SF as the distance from the mask MK increases.

When the method MT is applied to the substrate W2 shown in FIG. 6, the recess RE can be formed in each of the first region SF1 and the second region SF2. In the substrate W2, the second region SF2 is arranged alongside the first region SF1 in the in-plane direction of the substrate W2. The mask MK may have a hole-shaped opening (first opening OP1) on the first region SF1 and a slit-shaped opening (second opening OP2) on the second region SF2. The second ratio in the second region SF2 in which the slit-shaped opening is formed may be different from the first ratio in the first region SF1 in which the hole-shaped opening is formed. When the second ratio is larger than the first ratio, the etching rate of the second region SF2 can be increased. When the second ratio is smaller than the first ratio, the etching rate of the first region SF1 can be increased. Therefore, by making the first ratio and the second ratio different, a difference between the etching rate of the first region SF1 and the etching rate of the second region SF2 can be adjusted. For example, the second ratio may be larger than the first ratio. The second region SF2 in which the slit-shaped opening is formed often includes a silicon oxide film. The first region SF1 in which the hole-shaped opening is formed often includes a silicon nitride film or a silicon oxynitride film. The etching rate for the silicon oxide film tends to be smaller than the etching rate for the silicon nitride film or the silicon oxynitride film. Therefore, since the second ratio is larger than the first ratio, the etching rate of the second region SF2 can be increased. As a result, the difference between the etching rate of the first region SF1 and the etching rate of the second region SF2 can be reduced.

Although various exemplary embodiments have been described above, various additions, omissions, substitutions, and changes may be made without being limited to the above-described exemplary embodiments. Further, it is possible to form other embodiments by combining elements in different embodiments. For example, at least one of the silicon-containing film SF and the mask MK may include the additive element. When the mask MK includes the additive element, the additive element included in the mask MK can adhere to the sidewall REa of the recess RE formed in the silicon-containing film SF as a result of the mask MK being etched. As a result, adsorption of the hydrogen fluoride chemical species to the sidewall REa is promoted. A protective film DP is formed on the sidewall REa of the recess RE of the silicon-containing film SF by a reaction between the sidewall REa to which the additive element is attached and the hydrogen fluoride chemical species.

Hereinafter, an experiment conducted for evaluation of the method MT will be described. The experiment described below does not limit the present disclosure.

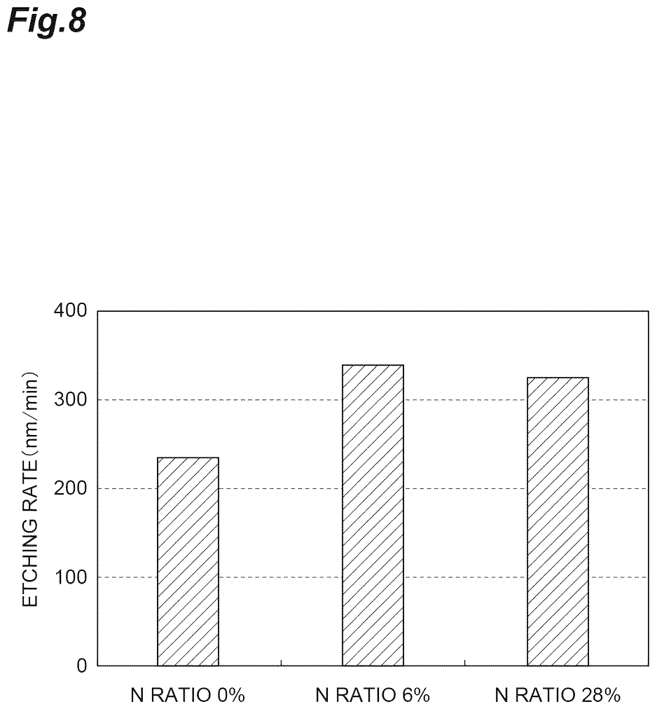

FIG. 8 is a diagram illustrating an example of experimental results regarding a difference in etching rate according to a ratio of nitrogen contained in the silicon-containing film SF. In the experiment, a substrate including a silicon-containing film to be etched was prepared. As samples of the substrate, a first sample not doped with nitrogen, a second sample doped with nitrogen at a ratio of 6 atomic %, and a third sample doped with nitrogen at a ratio of 28 atomic % were prepared for a silicon oxide film. The silicon-containing film of each sample was formed by a plasma enhanced chemical vapor deposition (PECVD) method. After loading the substrate into the plasma processing chamber, the film to be etched was etched by plasma generated from a processing gas. A hydrogen fluoride gas was used as the processing gas.

(Experimental Results) As shown in FIG. 8, the etching rates of the second sample and the third sample doped with nitrogen were about 1.5 times the etching rate of the first sample not doped with nitrogen. From this result, it was found that doping with nitrogen promoted adsorption of hydrogen fluoride chemical species to the silicon-containing film and improved the etching rate. On the other hand, it was found that there was no significant difference between the etching rate of the second sample doped with nitrogen at a ratio of 6 atomic % and the etching rate of the third sample doped with nitrogen at a ratio of 28 atomic %. In other words, it was found that the influence of the magnitude of the nitrogen ratio on the etching rate is small, and that the inclusion of nitrogen in the silicon-containing film has an effect of improving the etching rate even if the ratio is small.

Here, various exemplary embodiments included in the present disclosure are described in [E1] to [E20] below.
[E1]
   An etching method, comprising:
      (a) a step of loading a substrate into a chamber of a plasma processing apparatus, wherein the substrate has a silicon-containing film and a mask provided on the silicon-containing film, and the silicon-containing film includes at least one element selected from the group consisting of nitrogen, phosphorus, and boron; and
      (b) a step of exposing the substrate to plasma generated from a processing gas including a hydrogen fluoride gas,
         wherein the step (b) includes forming a recess in the silicon-containing film and forming a protective film including the at least one element on a sidewall of the recess.
[E2]
   The etching method according to [E1],
      wherein the silicon-containing film includes nitrogen, and
      the silicon-containing film includes at least one element selected from the group consisting of phosphorus and boron.
[E3]
   The etching method according to [E2],
      wherein the silicon-containing film includes at least one selected from the group consisting of a silicon nitride film and a silicon oxynitride film.
[E4]
   The etching method according to [E1],
      wherein the silicon-containing film includes a silicon oxide film including the at least one element.
[E5]
   The etching method according to any one of [E1] to [E4],
      wherein a ratio of the at least one element contained in the silicon-containing film is 10 atomic % or less.
[E6]
   The etching method according to any one of [E1] to [E5],
      wherein the silicon-containing film includes nitrogen, and
      the protective film includes ammonium fluorosilicate.
[E7]
   The etching method according to any one of [E1] to [E6],
      wherein the silicon-containing film has a first region including the at least one element at a first ratio, and a second region including the at least one element at a second ratio different from the first ratio.
[E8]
   The etching method according to [E7],
      wherein the second region is provided on the first region in a thickness direction of the substrate, and
      the second ratio is larger than the first ratio.
[E9]
   The etching method according to [E7],
      wherein the second region is provided on the first region in a thickness direction of the substrate, and
      the second ratio is smaller than the first ratio.
[E10]
   The etching method according to [E7],
      wherein the second region is arranged alongside the first region in an in-plane direction of the substrate, and
      the mask has a hole-shaped opening on the first region and a slit-shaped opening on the second region.
[E11]
   The etching method according to any one of [E1] to [E10],
      wherein the processing gas includes at least one selected from the group consisting of a nitrogen-containing gas, a phosphorus-containing gas, a carbon-containing gas, a gas containing a halogen other than fluorine, a boron-containing gas, and an oxygen-containing gas.
[E12]
   The etching method according to any one of [E1] to [E11],
      wherein in the step (b), a temperature of a substrate support that supports the substrate is set to 0° C. or lower.
[E13]
   The etching method according to any one of [E1] to [E12],
      wherein the mask includes at least one selected from the group consisting of silicon, carbon, and metal.
[E14]
   An etching method, comprising:
      (a) a step of loading a substrate into a chamber of a plasma processing apparatus, wherein the substrate has a silicon-containing film and a mask provided on the silicon-containing film, and at least one of the silicon-containing film and the mask includes at least one element selected from the group consisting of nitrogen, phosphorus, and boron; and
      (b) a step of exposing the substrate to plasma generated from a processing gas including fluorine and hydrogen,
         wherein the step (b) includes a step of forming a recess in the silicon-containing film and a step of forming a protective film including the at least one element on a sidewall of the recess, and the plasma includes a hydrogen fluoride etchant.
[E15]
   The etching method according to [E14], wherein in the step (b),
      the recess is formed by etching the silicon-containing film with the hydrogen fluoride etchant.
[E16]
   The etching method according to [E14] or [E15],
      wherein the processing gas includes a gas of a compound including hydrogen and fluorine, or is a mixed gas including a hydrogen-containing gas and a fluorine-containing gas.
[E17]
   The etching method according to [E16],
      wherein the gas of the compound includes at least one selected from the group consisting of a hydrogen fluoride gas and a hydrofluorocarbon gas.
[E18]
   The etching method according to [E16],
      wherein the hydrogen-containing gas included in the mixed gas includes at least one selected from the group consisting of H₂ gas, NH₃ gas, H₂O gas, H₂O₂ gas, and a hydrocarbon gas.
[E19]
   The etching method according to [E16],
      wherein the fluorine-containing gas included in the mixed gas includes at least one selected from the group consisting of NF₃ gas, SF₆ gas, WF₆ gas, XeF₂ gas, a fluorocarbon gas, and a hydrofluorocarbon gas.
[E20]
   A plasma processing apparatus, comprising:
      a chamber;
      a substrate support for supporting a substrate in the chamber, wherein the substrate has a silicon-containing film and a mask provided on the silicon-containing film, and the silicon-containing film includes at least one element selected from the group consisting of nitrogen, phosphorus, and boron;
      a gas supply configured to supply a processing gas including a hydrogen fluoride gas into the chamber; a plasma generator configured to generate plasma from the processing gas; and
      a controller configured to control the plasma processing apparatus to execute an etching method including:
         (a) a step of loading the substrate into the chamber; and
         (b) a step of exposing the substrate to the plasma, the step including a step of forming a recess in the silicon-containing film and a step of forming a protective film including the at least one element on a sidewall of the recess.

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. An etching method, comprising:
loading a substrate into a chamber of a plasma processing apparatus, the substrate having a silicon-containing film and a mask on the silicon-containing film, and the silicon-containing film including at least one element selected from the group consisting of nitrogen, phosphorus, and boron; and
exposing the substrate to plasma generated from a processing gas including a hydrogen fluoride gas,
wherein the exposing includes forming a recess in the silicon-containing film and forming a protective film including the at least one element on a sidewall of the recess.

2. The etching method according to claim 1, wherein
the silicon-containing film includes nitrogen, and
the silicon-containing film includes at least one element selected from the group consisting of phosphorus and boron.

3. The etching method according to claim 2, wherein
the silicon-containing film includes at least one selected from the group consisting of a silicon nitride film and a silicon oxynitride film.

4. The etching method according to claim 1, wherein
the silicon-containing film includes a silicon oxide film including the at least one element.

5. The etching method according to claim 1, wherein
a ratio of the at least one element contained in the silicon-containing film is 10 atomic % or less.

6. The etching method according to claim 1, wherein
the silicon-containing film includes nitrogen, and
the protective film includes ammonium fluorosilicate.

7. The etching method according to claim 1, wherein
the silicon-containing film has a first region including the at least one element at a first ratio, and a second region including the at least one element at a second ratio different from the first ratio.

8. The etching method according to claim 7, wherein
the second region is on the first region in a thickness direction of the substrate, and
the second ratio is larger than the first ratio.

9. The etching method according to claim 7, wherein
the second region is on the first region in a thickness direction of the substrate, and
the second ratio is smaller than the first ratio.

10. The etching method according to claim 7, wherein
the second region is alongside the first region in an in-plane direction of the substrate, and
the mask has a hole-shaped opening on the first region and a slit-shaped opening on the second region.

11. The etching method according to claim 1, wherein
the processing gas includes at least one selected from the group consisting of a nitrogen-containing gas, a phosphorus-containing gas, a carbon-containing gas, a gas containing a halogen other than fluorine, a boron-containing gas, and an oxygen-containing gas.

12. The etching method according to claim 1, wherein
in the exposing, a temperature of a substrate support that supports the substrate is set to 0° C. or lower.

13. The etching method according to claim 1, wherein
the mask includes at least one selected from the group consisting of silicon, carbon, and metal.

14. An etching method, comprising:
loading a substrate into a chamber of a plasma processing apparatus, the substrate having a silicon-containing film and a mask on the silicon-containing film, and at least one of the silicon-containing film and the mask including at least one element selected from the group consisting of nitrogen, phosphorus, and boron; and
exposing the substrate to plasma generated from a processing gas including fluorine and hydrogen,
wherein the exposing includes forming a recess in the silicon-containing film and forming a protective film including the at least one element on a sidewall of the recess, and the plasma includes a hydrogen fluoride etchant.

15. The etching method according to claim 14, wherein
in the exposing, the recess is formed by etching the silicon-containing film with the hydrogen fluoride etchant.

16. The etching method according to claim 14, wherein
the processing gas includes a gas of a compound including hydrogen and fluorine, or is a mixed gas including a hydrogen-containing gas and a fluorine-containing gas.

17. The etching method according to claim 16, wherein
the gas of the compound includes at least one selected from the group consisting of a hydrogen fluoride gas and a hydrofluorocarbon gas.

18. The etching method according to claim 16, wherein
the hydrogen-containing gas included in the mixed gas includes at least one selected from the group consisting of H₂ gas, NH₃ gas, H₂O gas, H₂O₂ gas, and a hydrocarbon gas.

19. The etching method according to claim 16, wherein
the fluorine-containing gas included in the mixed gas includes at least one selected from the group consisting of NF₃ gas, SF₆ gas, WF₆ gas, XeF₂ gas, a fluorocarbon gas, and a hydrofluorocarbon gas.

20. A plasma processing apparatus, comprising:
a chamber;
a substrate support configured to support a substrate in the chamber, wherein the substrate has a silicon-containing film and a mask on the silicon-containing film, and the silicon-containing film including at least one element selected from the group consisting of nitrogen, phosphorus, and boron;
a gas supply configured to supply a processing gas including a hydrogen fluoride gas into the chamber;
a plasma generator configured to generate plasma from the processing gas; and
a controller configured to control the plasma processing apparatus to execute an etching method, the method including:
loading the substrate into the chamber; and
exposing the substrate to the plasma, the exposing including forming a recess in the silicon-containing film and forming a protective film including the at least one element on a sidewall of the recess.
